(19) United States
(12) Patent Application Publication
(10) Pub. No.: US 2024/0357837 A1
(43) Pub. Date: Oct. 24, 2024

(54) CONTACT FORMATION FOR A MEMORY DEVICE

(71) Applicant: Micron Technology, Inc., Boise, ID (US)

(72) Inventors: Darwin A. Clampitt, Wilder, ID (US); Stephen W. Russell, Boise, ID (US); Steven P. Turini, Boise, ID (US); Farrell M. Good, Meridian, ID (US); Kolya Yastrebenetsky, Boise, ID (US); Nirav Vora, Meridian, ID (US); Zhao Zhao, Meridian, ID (US)

(21) Appl. No.: 18/642,555

(22) Filed: Apr. 22, 2024

Related U.S. Application Data
(60) Provisional application No. 63/461,461, filed on Apr. 24, 2023.

(51) Int. Cl. H10B 63/00; H10B 63/10

(52) U.S. Cl. CPC H10B 63/845; H10B 63/10

(57) ABSTRACT

Methods, systems, and devices for contact formation for a memory device are described. A memory device manufacturing operation may include forming bit lines and word lines in a same step. In some cases, the memory device may include word line contact portions that couple respective word lines with respective word line contacts located below the word lines. For example, the word line contact portions may be located between word lines and a substrate of the memory array. In such cases, the processing step may be used for formation of word lines, bit lines, and word line contact portions. Additionally, or alternatively, the memory device manufacturing operation may include forming a sacrificial ring around bit line contacts, which may isolate bit line contacts from a nitride layer.

### CROSS REFERENCE

The present application for patent claims priority to U.S. Patent Application No. 63/461,461 by Clampitt et al., entitled “CONTACT FORMATION FOR A MEMORY DEVICE,” filed Apr. 24, 2023, which is assigned to the assignee hereof, and which is expressly incorporated by reference in its entirety herein.

### TECHNICAL FIELD

The following relates to one or more systems for memory, including contact formation for a memory device.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not- or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports contact formation for a memory device in accordance with examples as disclosed herein.

FIG. 2 shows an example of a material arrangement that supports contact formation for a memory device in accordance with examples as disclosed herein.

FIGS. 3A and 3B show examples of material arrangements that support contact formation for a memory device in accordance with examples as disclosed herein.

FIG. 4 shows an example of a material arrangement that supports contact formation for a memory device in accordance with examples as disclosed herein.

FIG. 5 shows an example of a material arrangement that supports contact formation for a memory device in accordance with examples as disclosed herein.

FIG. 6 shows an example of a material arrangement that supports contact formation for a memory device in accordance with examples as disclosed herein.

FIG. 7 shows an example of a material arrangement that supports contact formation for a memory device in accordance with examples as disclosed herein.

FIG. 8A shows an example of a process that supports contact formation for a memory device in accordance with examples as disclosed herein

FIG. 8B shows an example of a material arrangement that supports contact formation for a memory device in accordance with examples as disclosed herein.

FIG. 9A shows an example of a process that supports contact formation for a memory device in accordance with examples as disclosed herein.

FIGS. 9B through 9C show examples of material arrangements that support contact formation for a memory device in accordance with examples as disclosed herein.

FIGS. 10 and 11 show flowcharts illustrating a method or methods that support contact formation for a memory device in accordance with examples as disclosed herein.

### DETAILED DESCRIPTION

Some memory devices may include a substrate and an array formed above the substrate. In some cases, the array may include word lines, bit lines, and memory cells, while the substrate may include contacts (e.g., back-end-of-line (BEOL) contacts) for coupling word lines and bit lines with circuitry formed in the substrate or below the substrate. In some cases, a memory device manufacturing operation may utilize a same material (e.g., a same metal) to form word lines and bit lines. In some instances, word lines may be formed using a first processing step and bit lines may be formed using a second processing step, which may increase complexity and reduce the accuracy of the manufacturing operations (e.g., due to error associated with each step compounding). Additionally, or alternatively, contacts formed in a substrate of a memory device may extend through a sacrificial layer (e.g., a sacrificial nitride layer for subsequent formation of a horizontal interconnect layer), which may eventually be removed using an etching solution. In such cases, the etching solution may inadvertently touch the contacts and be contaminated with portions of a material used for forming the contacts (e.g., tungsten), which may result in defects or performance issues at the memory system.

In accordance with examples as descried herein, processes used to manufacture memory devices may include forming bit lines and word lines in a same processing step, which may improve processing accuracy (e.g., alignment of memory device components) and processing speed. In some cases, the memory device may include word line contact portions that couple respective word lines with respective word line contacts (e.g., BEOL contacts). In such cases, word line contact portions may extend from respective word lines to word line contacts located below the word lines (e.g., that extend to a substrate of the memory device). In such cases, the processing step may be used to form word lines, bit lines, and word line contact portions, further improving processing accuracy and processing speed for the manufacturing operation. Additionally, or alternatively, the memory device manufacturing operation may include forming a sacrificial ring around contacts (e.g., BEOL contacts, bit line contacts), which may isolate the contacts from the sacrificial layer, resulting in a reduced likelihood of the etching solution being contaminated.

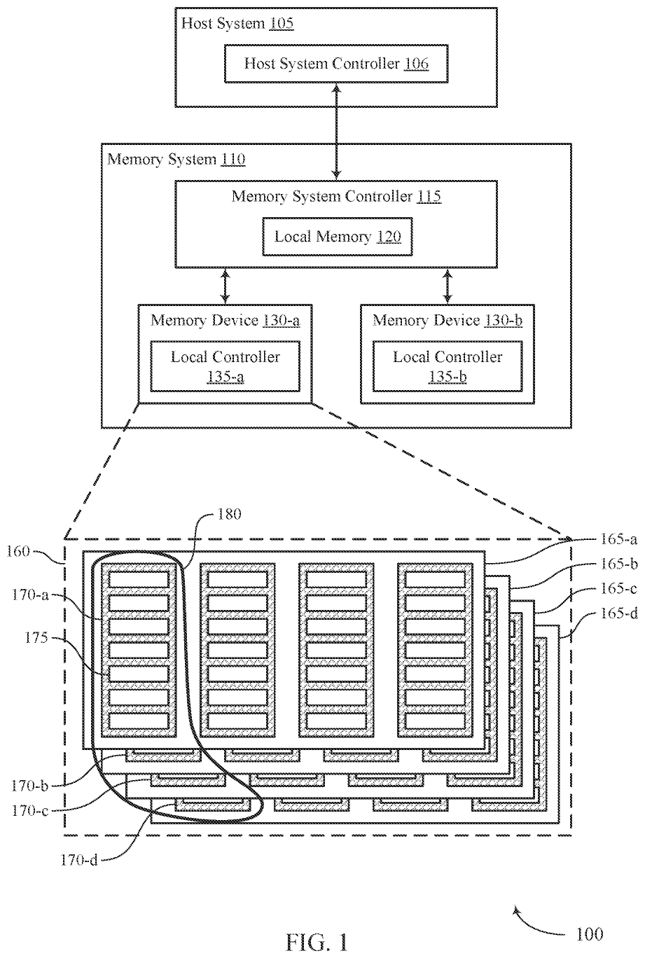

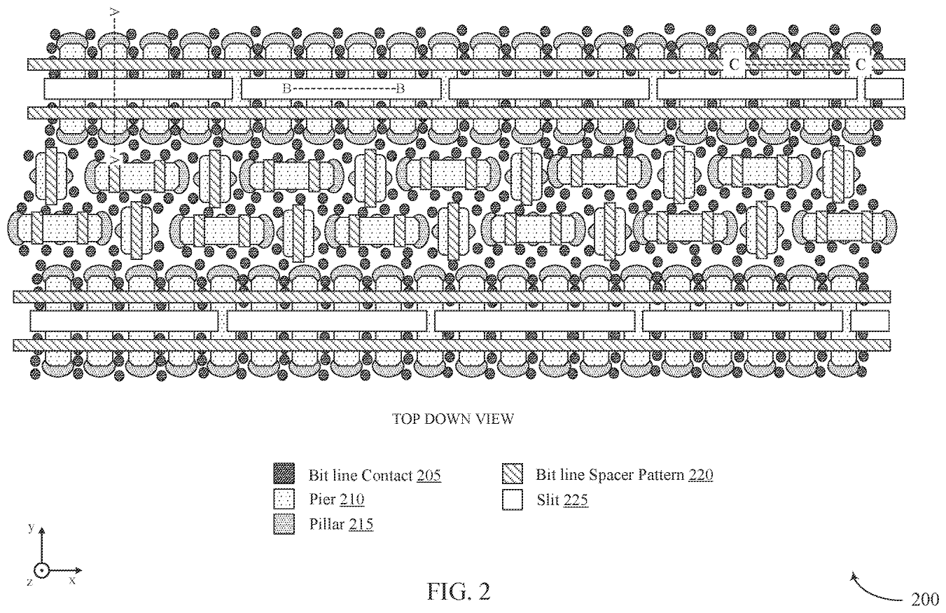

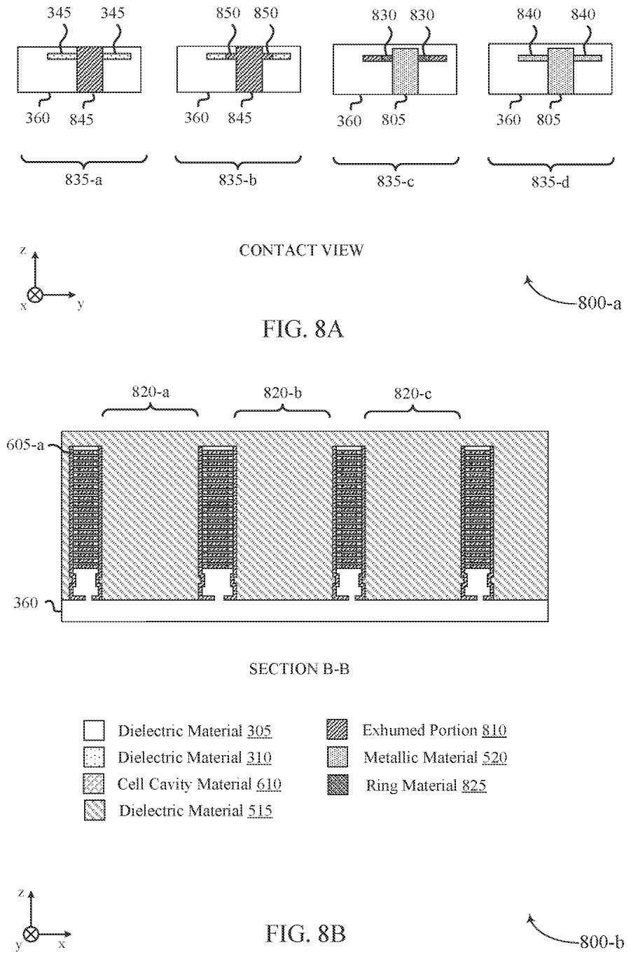

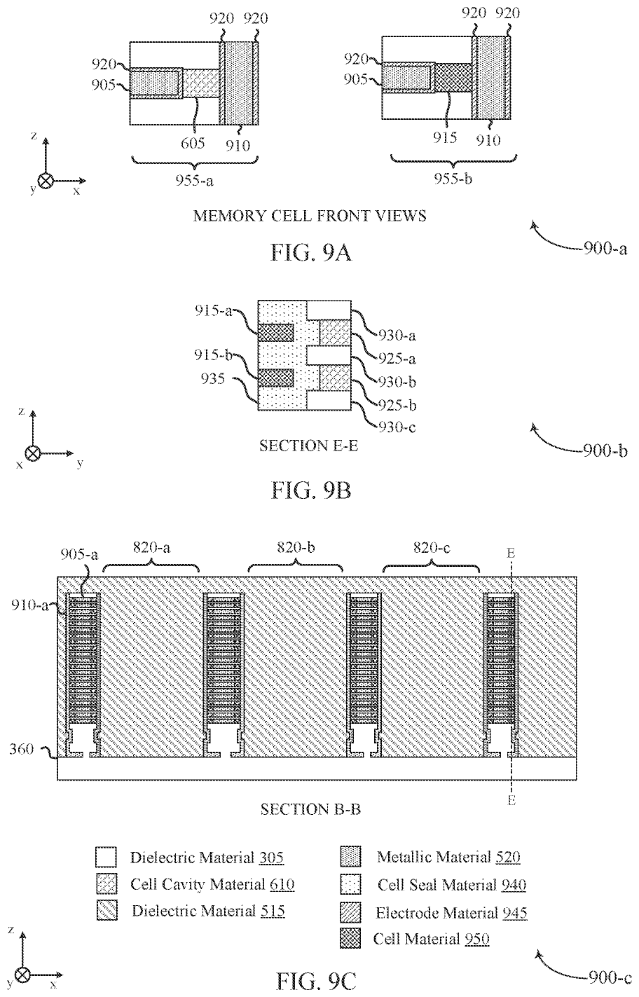

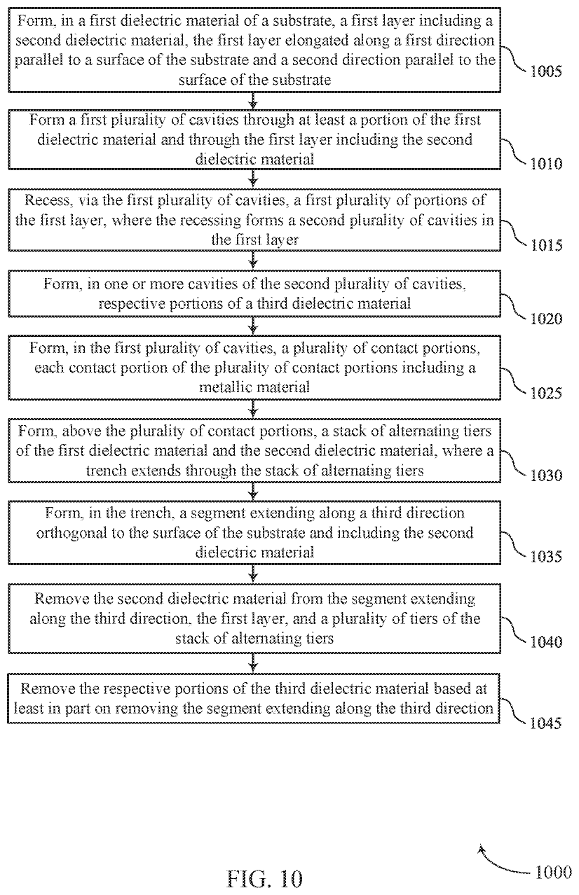

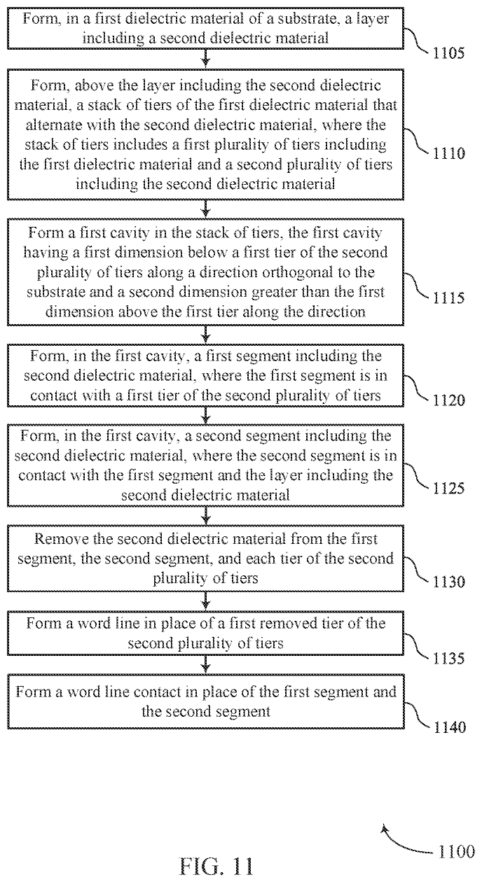

Features of the disclosure are initially described in the context of a system with reference to FIG. 1. Features of the disclosure are described in the context of material arrangements with reference to FIGS. 2 through 7, as well as FIGS. 8B, 9B, and 9C. Features of the disclosure are also described in the context of a process with reference to FIGS. 8A and 9A. These and other features of the disclosure are further illustrated by and described in the context of flowcharts that relate to contact formation for a memory device with reference to FIGS. 10 through 11.

FIG. 1 shows an example of a system 100 that supports contact formation for a memory device in accordance with examples as disclosed herein. The system 100 includes a host system 105 coupled with a memory system 110. The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically crasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165 (e.g., any of a plane 165-a, a plane 165-b, a plane 165-c, and a plane 165-d), and each plane 165 may include a respective set of blocks 170 (e.g., any of a block 170-a, a block 170b-, a block 170-c, and a block 170-d), where each block 170 may include a respective set of pages 175, and each page 175 may include a set of memory cells.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

A memory device 130 may include one or more memory cells that each may be programmable to store different logic states (e.g., a programmed one of a set of two or more possible states). For example, a memory cell may be operable to store one bit of information at a time (e.g., a logic 0 or a logic 1). In some examples, a memory cell (e.g., a multi-level memory cell) may be operable to store more than one bit of information at a time (e.g., a logic 00, logic 01, logic 10, a logic 11). In some examples, memory cells may be arranged in an array.

A memory cell may store a logic state using a configurable material, which may be referred to as a memory element, a storage element, a memory storage element, a material element, a material memory element, a material portion, or a polarity-written material portion, among others. A configurable material of a memory cell may refer to a chalcogenide-based storage component. For example, a chalcogenide storage element may be used in a phase change memory cell, a thresholding memory cell, or a self-selecting memory cell, among other architectures.

In some examples, the material of a memory cell may include a chalcogenide material or other alloy including selenium (Se), tellurium (Te), arsenic (As), antimony (Sb), carbon (C), germanium (Ge), silicon (Si), or indium (In), or various combinations thereof. In some examples, a chalcogenide material having primarily selenium (Se), arsenic (As), and germanium (Ge) may be referred to as a SAG-alloy. In some examples, a SAG-alloy may also include silicon (Si) and such chalcogenide material may be referred to as SiSAG-alloy. In some examples, SAG-alloy may include silicon (Si) or indium (In) or a combination thereof and such chalcogenide materials may be referred to as SiSAG-alloy or InSAG-alloy, respectively, or a combination thereof. In some examples, the chalcogenide material may include additional elements such as hydrogen (H), oxygen (O), nitrogen (N), chlorine (Cl), or fluorine (F), each in atomic or molecular forms.

In some examples, a memory cell may be an example of a phase change memory cell. In such examples, the material used in the memory cell may be based on an alloy (such as the alloys listed above) and may be operated so as to change to different physical state (e.g., undergo a phase change) during normal operation of the memory cell. For example, a phase change memory cell may be associated with a relatively disordered atomic configuration (e.g., a relatively amorphous state) and a relatively ordered atomic configuration (e.g., a relatively crystalline state). A relatively disordered atomic configuration may correspond to a first logic state (e.g., a RESET state, a logic 0) and a relatively ordered atomic configuration may correspond to a second logic state (e.g., a logic state different than the first logic state, a SET state, a logic 1).

In some examples (e.g., for thresholding memory cells, for self-selecting memory cells), some or all of the set of logic states supported by the memory cells may be associated with a relatively disordered atomic configuration of a chalcogenide material (e.g., the material in an amorphous state may be operable to store different logic states). In some examples, the storage element of a memory cell may be an example of a self-selecting storage element. In such examples, the material used in the memory cell may be based on an alloy (e.g., such as the alloys listed above) and may be operated so as to undergo a change to a different physical state during normal operation of the memory cell. For example, a self-selecting or thresholding memory cell may have a high threshold voltage state and a low threshold voltage state. A high threshold voltage state may correspond to a first logic state (e.g., a RESET state, a logic 0) and a low threshold voltage state may correspond to a second logic state (e.g., a logic state different than the first logic state, a SET state, a logic 1).

During a write operation (e.g., a programming operation) of a self-selecting or thresholding memory cell, a polarity used for a write operation may influence (e.g., determine, set, program) a behavior or characteristic of the material of the memory cell, such as a thresholding characteristic (e.g., a threshold voltage) of the material. A difference between thresholding characteristics of the material of the memory cell for different logic states stored by the material of the memory cell (e.g., a difference between threshold voltages when the material is storing a logic state ‘0’ versus a logic state ‘1’) may correspond to the read window of the memory cell.

The memory device 130 may include access lines (e.g., row lines, column lines) arranged in a pattern, such as a grid-like pattern. Access lines may be formed with one or more conductive materials. In some examples, row lines, or some portion thereof, may be referred to as word lines. In some examples, column lines, or some portion thereof, may be referred to as digit lines or bit lines. References to access lines, or their analogues, are interchangeable without loss of understanding. Memory cells may be positioned at intersections of access lines, such as row lines and the column lines. In some examples, memory cells may be located at different levels (e.g., layers, decks, planes, tiers) of a memory array.

Operations such as read operations and write operations may be performed on the memory cells by activating access lines such as one or more of a row line or a column line, among other access lines associated with alternative configurations. For example, by activating a row line and a column line (e.g., applying a voltage to the row line or the column line), a memory cell may be accessed in accordance with their intersection. An intersection of a row line and a column line, among other access lines, in various two-dimensional or three-dimensional configuration may be referred to as an address of a memory cell. In some examples, an access line may be a conductive line coupled with a memory cell and may be used to perform access operations on the memory cell. In some examples, the memory device 130 may perform operations responsive to commands, which may be issued by a host system 105 (e.g., a host system controller 106) coupled with the memory device 130 or may be generated by the memory device 130 (e.g., by a local controller 135).

Accessing the memory cells may be controlled through one or more decoders, such as a row decoder or a column decoder, among other examples. For example, a row decoder may receive a row address from a local controller 135 and activate a row line based on the received row address. A column decoder may receive a column address from a local controller 135 and may activate a column line based on the received column address.

A sense component may be operable to detect a state (e.g., a material state, a resistance state, a threshold state) of a memory cell and determine a logic state of the memory cell based on the detected state. The sense component may include one or more sense amplifiers to convert (e.g., amplify) a signal resulting from accessing the memory cell (e.g., a signal of a column line or other access line). The sense component may compare a signal detected from the memory cell to a reference (e.g., a reference voltage, a reference charge, a reference current). The detected logic state of the memory cell may be provided as an output of the sense component (e.g., to an input/output component), and may indicate the detected logic state to another component of the memory device 130 or to a host system 105 coupled with the memory device 130.

A local controller 135 may control the accessing of memory cells through the various components (e.g., a row decoder, a column decoder, a sense component, among other components). In some examples, one or more of a row decoder, a column decoder, and a sense component may be co-located with a local controller 135. The local controller 135 may be operable to receive information (e.g., commands, data) from one or more different controllers (e.g., an external memory controller associated with a host system 105, another controller associated with the memory device 130), translate the information into a signaling that can be used by the memory device 130, perform one or more operations on the memory cells and communicate data from the memory device 130 to a host system 105 based on performing the one or more operations. The local controller 135 may generate row address signals and column address signals to activate access lines such as a target row line and a target column line. The local controller 135 also may generate and control various signals (e.g., voltages, currents) used during the operation of the memory device 130. In general, the amplitude, the shape, or the duration of an applied signal discussed herein may be varied and may be different for the various operations discussed in operating the memory device 130.

A local controller 135 may be operable to perform one or more access operations on one or more memory cells of the memory device 130. Examples of access operations may include a write operation, a read operation, a refresh operation, a precharge operation, or an activate operation, among others. In some examples, access operations may be performed by or otherwise coordinated by the local controller 135 in response to access commands (e.g., from a host system 105). The local controller 135 may be operable to perform other access operations not listed here or other operations related to the operating of the memory device 130 that are not directly related to accessing the memory cells.

Some memory devices 130 may include a substrate and an array formed above the substrate. In some cases, the array may include word lines, bit lines, and memory cells, while the substrate may include contacts (e.g., back-end-of-line (BEOL) contacts) for coupling word lines and bit lines with circuitry formed in the substrate or below the substrate. In some cases, a memory device 130 manufacturing operation may utilize a same material (e.g., a same metallic material) to form word lines and bit lines. In some instances, word lines may be formed using a first processing step and bit lines may be formed using a second processing step, which may increase complexity and reduce the accuracy of the manufacturing operations (e.g., due to error associated with each step compounding). Additionally, or alternatively, contacts formed in a substrate of a memory device may extend through a sacrificial layer (e.g., a sacrificial nitride layer for subsequent formation of a word line interconnect layer), which may eventually be removed using an etching solution. In such cases, the etching solution may inadvertently touch the contacts and be contaminated with portions of a material used for forming the contacts (e.g., tungsten), which may result in defects or performance issues at the memory system 110.

In accordance with examples as descried herein, processes used to manufacture memory devices 130 may include forming bit lines and word lines in a same processing step, which may improve processing accuracy (e.g., alignment of memory device 130 components) and processing speed. In some cases, the memory device 130 may include word line contact portions that couple respective word lines with respective word line contacts (e.g., BEOL contacts). In such cases, word line contact portions may extend from respective word lines to word line BEOL contacts located below word lines (e.g., in a substrate of the memory device 130). In such cases, the processing step may be used to form word lines, bit lines, and word line contact portions, further improving processing accuracy and processing speed for the manufacturing operation. Additionally, or alternatively, the memory device 130 manufacturing operation may include forming a sacrificial ring around contacts (e.g., BEOL contacts, bit line contacts), which may isolate the contacts from the sacrificial layer, resulting in a reduced likelihood of the etching solution being contaminated.

In addition to applicability in memory systems 110 as described herein, techniques for contact formation for a memory device may be generally implemented to support edge computing applications. Edge computing is a distributed computing paradigm that brings computation and data storage closer to the sources of data than traditional cloud services. As the use of edge computing to provide computing, storage, and networking services at locations that are geographically closer to end users increases, many devices and systems may benefit from improved processing, performance, and storage at edge devices. For example, increasing memory density, capacity, and processing power of edge devices may decrease a reliance on the devices to remote computing or devices, which may otherwise increase latency of operations performed at the devices. Implementing the techniques described herein may support edge computing techniques by increasing memory capacity associated with edge computing devices and improving response times associated with edge computing devices, among other benefits.

FIG. 2 shows an example of a material arrangement 200 that supports contact formation for a memory device in accordance with examples as disclosed herein. In some cases, one or more aspects of the material arrangement 200 may be implemented by one or more aspects of the system 100. For example, the material arrangement 200 may illustrate a top down view of one or more aspects of a memory device 130, as described with reference to FIG. 1. The material arrangement 200 may include bit line contacts 205, piers 210, pillars 215, bit line spacer patterns 220, and slits 225. While the material arrangement 200 may include one or more aspects of the memory device 130, the material arrangement 200 may also omit one or more aspects of the memory device (e.g., for illustrative clarity). Aspects of the material arrangement 200 may be arranged with respect to an x-direction (e.g., a first direction), a y-direction (e.g., a second direction), and a z-direction (e.g., a third direction).

The material arrangement 200 may include a plurality of bit line contacts 205 (e.g., digit line contacts), which may be formed using a metallic material (e.g., tungsten, molybdenum, or a combination thereof). Bit line contacts 205 may be arranged along the x-direction and along the y-direction. Additionally, or alternatively, each bit line contact 205 may be formed in a cylindrical shape with a height that extends along the z-direction. In some cases, bit line contacts 205 may be formed in a substrate (not shown) of a memory device 130. For example, the substrate may be elongated along the x-direction and the y-direction and bit line contacts 205 may extend through at least a portion of the substrate. Although some components of the material arrangement 200 may appear to be shown as above bit line contacts 205, such components may be arranged in any order with respect to the z-direction. For example, some components of the material arrangement 200 may be located below or partially below bit line contacts 205. Additionally, or alternatively, some components of the material arrangement 200 may be overlapping or partially overlapping with respect to the z-direction.

In some cases, bit line contacts 205 may extend through a word line interconnect layer (not shown). Additionally, or alternatively, each bit line contact 205 may be formed in a respective cavity. For example, a plurality of cavities (e.g., a first plurality of cavities) may be formed through at least a portion of a substrate of the memory device 130. Each cavity may be formed in a cylindrical shape (e.g., with a height axis extending along the z-direction) and each bit line contact 205 may be formed in a respective cavity. In some cases, each bit line contact 205 may be coupled with a respective bit line of the memory device 130, or other circuitry coupled with bit lines (e.g., bit line driver circuitry).

The material arrangement 200 may include a plurality of piers 210 (e.g., bit line and cell formation piers). The piers 210 may be arranged along the x-direction and along the y-direction. In some cases, piers 210 may be examples of openings (e.g., trenches, cavities) that provide access to various portions of a memory device 130 (e.g., for processing operations). For example, a pier 210 may enable the formation of bit lines and memory cells. In some cases, a size of a pier 210 may depend on (e.g., may be based on) a layout of a memory device 130 that includes the pier 210. For example, a size of a pier 210 may be based on a quantity of bit lines and memory cells that are formed via the pier 210. Each pier 210 may have a first dimension along the x-direction, a second dimension along the z-direction and a third dimension along the y-direction. In some cases, a depth of a pier 210 may extend via one or more layers of a memory device 130 and terminate at a landing pad (not shown) (e.g., a pier landing pad).

The material arrangement 200 may include a plurality of pillars 215 (e.g., replacement gate and cell deposition pillars). The pillars 215 may be arranged along the x-direction and along the y-direction. In some cases, pillars 215 may be examples of openings (e.g., trenches, cavities) that provide access to various portions of a memory device 130 (e.g., for processing operations). For example, a pillar 215 may enable the formation of replacement gates and memory cells of a memory device 130. Additionally, or alternatively, each pillar 215 may be formed in a cylindrical shape with a height that extends along the z-direction. In some cases, a depth of a pillar 215 may extend via one or more layers of a memory device 130 and terminate at a landing pad (not shown) (e.g., a pillar landing pad).

The material arrangement 200 may include a plurality of bit line spacer patterns 220 (e.g., bit line spacer segmentation patterns, bit line segmentation patterns). The bit line spacer patterns 220 may be arranged along the x-direction and along the y-direction. In some cases, the bit line spacer patterns 220 may be examples of openings (e.g., trenches, cavities) that provide access to various portions of a memory device 130 (e.g., for processing operations). For example, a bit line spacer pattern 220 may enable the formation of bit line contacts and word line contacts. In some cases, each bit line spacer pattern 220 may be formed in a rectangular shape and may extend through a portion of layers of the memory device 130. Additionally, or alternatively, each bit line spacer pattern 220 may be formed using a patterning operation, an etching operation (e.g., a dry develop etching operation), or both.

The material arrangement 200 may include a plurality of slits 225 (e.g., replacement gate and cell deposition slits). The slits 225 may be arranged along the x-direction and along the y-direction. In some cases, the slits 225 may be examples of openings (e.g., trenches, cavities) that provide access to various portions of a memory device 130 (e.g., for processing operations). For example, a slit 225 may enable the formation of replacement gates and memory cells. In some cases, each slit 225 may be formed in a rectangular shape and may extend through a portion of layers of the memory device 130. Additionally, or alternatively, each slit 225 may be formed using a patterning operation, an etching operation (e.g., a dry develop etching operation), or both. In some cases, a depth of a slit 225 may extend via one or more layers of a memory device 130 and terminate at a landing pad (not shown).

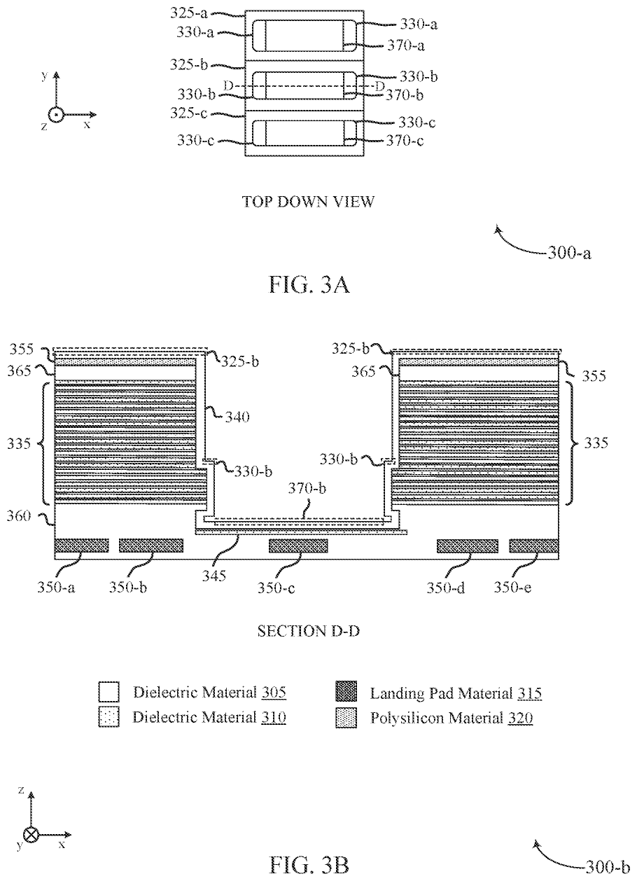

FIG. 3A shows an example of a material arrangement 300-a that supports contact formation for a memory device in accordance with examples as disclosed herein. In some cases, the material arrangement 300-a may be an example of a portion of one or more aspects of the system 100, such as a memory device 130. Additionally, or alternatively, the material arrangement 300-a may illustrate a top down view of one or more aspects of the material arrangement 300-b, as described with reference to FIG. 3B. For example, the material arrangement 300-a may illustrate various regions of the spacer 340, which is described in further detail with reference to FIG. 3B. The material arrangement 300-a may include regions 325, regions 330, and regions 370, some of which are also shown in FIG. 3B. For example, FIG. 3B shows region 325-b, region 330-b, and region 370-b, which are each bisected by the cross section D-D. In some cases, regions 330 (e.g., regions of the spacer 340) may be formed in accordance with a staircase pattern and may accordingly have different heights along the z-direction (e.g., surfaces of the spacer 340 included in the regions 330 may have different heights along the z-direction). For example, a surface of the spacer 340 included in the region 330-a may be above a surface of the spacer 340 included in the region 330-b with respect to the z-direction, and a surface of the spacer 340 included in the region 330-b may be above a surface of the spacer 340 included in the region 330-c with respect to the z-direction. Accordingly, each region 330 may correspond to a step in the staircase pattern.

The material arrangement 300-a may be an example of a portion of a memory device 130 after one or more manufacturing operations. For example, the material arrangement 300-a may include portions of the spacer 340, which may be deposited on a stack of alternating layers 335. The stack of alternating layers 335 may include a first set of layers formed using a first dielectric material and a second set of layers formed using a second dielectric material, which may be interleaved in the stack of alternating layers 335. The stack of alternating layers 335 may be formed above a substrate of the memory device 130 by depositing alternating layers of the first dielectric material and the second dielectric material. The staircase pattern may then be formed in the stack of alternating layers 335 by selectively removing portions of layers to create the staircase pattern.

The staircase pattern may include steps that descend in the negative z-direction as the staircase is traversed in the negative y-direction. As an illustrative example, a first layer in the stack of alternating layers 335 (e.g., a highest layer with respect to the z-direction), may form a first step of the staircase pattern. A portion of the first layer and a portion of the second layer below the first layer (e.g., with respect to the z-direction) may then be removed, which may expose a portion of the third layer. The exposed portion of the third layer may form a second step in the staircase pattern. As described herein, and as shown in FIG. 3B, the cross section D-D shows a ledge (e.g., extending in the x-direction) of a sixteenth step in the staircase pattern, where a portion of the spacer 340 in the region 330-b is formed (e.g., deposited) on the ledge of the sixteenth step. Accordingly, the portion of the spacer 340 in the region 330-c may be formed on a ledge of a seventeenth step of the staircase pattern and the portion of the spacer 340 in the region 330-a may be formed on a ledge of a fifteenth step of the staircase pattern.

While each region 330 corresponds to a portion of the spacer 340 having a different height with respect to the z-direction, other portions of the spacer 340 may have a same height with respect to the z-direction. For example, regions 325 may be formed above a layer 355, which may have a flat surface extending along the x-direction and the y-direction (e.g., the layer 355 may not be formed using the staircase pattern). Accordingly, the region 325-a, the region 325-b, and the region 325-c may have a same height with respect to the z-direction. Similarly, the regions 370 may be formed above a flat portion of the layer 360. Accordingly, the region 370-a, the region 370-b, and the region 370-c may have a same height with respect to the z-direction. Although FIG. 3A illustrates regions 325, regions 330, and regions 370 that correspond to three steps in the staircase pattern, the staircase pattern may include any quantity of steps and any quantity of regions 325, regions 330, and regions 370. For example, the staircase pattern may include a step for each word line of a memory device 130.

FIG. 3B shows an example of a material arrangement 300-b that supports contact formation for a memory device in accordance with examples as disclosed herein. In some cases, the material arrangement 300-b may be an example of a portion of one or more aspects of the system 100. For example, the material arrangement 300-b may illustrate a section view (e.g., section D-D of FIG. 3A) of one or more aspects of a memory device 130, as described with reference to FIG. 1. In some cases, the material arrangement 300-b may be an example of a word line contact staircase of a memory device 130 and may illustrate one or more processing operations used to form the word line contact staircase. As described herein, the word line contact staircase may be utilized for exposing portions (e.g., surfaces) of each word line for coupling with other components of the memory device 130.

The material arrangement 300-b may include a layer 360, which may be formed using a dielectric material 305 (e.g., an oxide material). In some cases, the layer 360 may be an example of a substrate. In some other cases, the layer 360 may be formed above a substrate. The layer 360 may have a width along the x-direction, a depth along the y-direction, and a height along the z-direction. In some cases, a plurality of landing pads 350 may be formed in the layer 360. For example, the layer 360 may include a landing pad 350-a, a landing pad 350-b, a landing pad 350-c, a landing pad 350-d, and a landing pad 350-c. Each landing pad 350 of the plurality of landing pads 350 may be formed using a landing pad material 315. The landing pad material 315 may be an example of a metallic material. In some cases, landing pads 350 may be arranged along the x-direction and along the y-direction.

In some cases, a placeholder for an interconnect layer 345 (e.g., a first layer) may be formed in the layer 360. The placeholder for the interconnect layer 345 may be formed using the dielectric material 310 (e.g., a nitride material). In some cases, the interconnect layer 345 may be formed above one or more landing pads 350 with respective to the z-direction. The interconnect layer 345 may be utilized for subsequently forming portions of word line contacts or otherwise coupling word lines with word line driver circuitry.

The material arrangement 300-b may include a stack of alternating layers 335. The stack of alternating layers 335 may include alternating layers of the dielectric material 305 and the dielectric material 310. The stack of alternating layers 335 may be formed above the layer 360. In some cases, one or more layers of the stack of alternating layers 335 may be removed and replaced with a metallic material during a word line formation operation. For example, each layer of the dielectric material 310 may be subsequently etched and replaced with the metallic material to form word lines (e.g., which may be formed as plates extending in the x and y directions). In some cases, the staircase formation, as described with reference to FIG. 3A may be formed in the stack of alternating layers 335.

In some cases, one or more layers may be formed above (e.g., with respect to the z-direction) the stack of alternating layers 335. For example, a top layer of the stack of alternating layers 335 may be patterned and etched, and a layer 365 (e.g., an oxide layer) may be formed above the top layer of the stack of alternating layers 335. In some cases, patterning and etching the top layer of the stack of alternating layers 335 may form a connection layer for coupling BEOL contacts with CMOS connection contacts. In such cases, formation of BEOL contacts may be performed insitu with word line contacts in the staircase pattern. In some cases, a layer 355 may be formed above the layer 365. The layer 355 may be formed using a polysilicon material 320. The polysilicon material 320 may be an example of a sacrificial material. In some cases, the stack of alternating layers 335, the layer 365, and the layer 355 may initially be formed as continuous layers (e.g., extending along the x-direction) and may subsequently be divided via the formation of one or more trenches (e.g., one or more cavities). For example, FIG. 3A shows a top down view of the material arrangement 300-a, which illustrates the geometry of the spacer 340, which is formed in the one or more trenches. A first trench of the one or more trenches may extend through a first portion of the stack of alternating layers 335 (e.g., in the negative z-direction) and may create the ledge that the portion of the spacer 340 in region 330-b is formed on. A second trench of the one or more trenches may extend through a second portion of the stack of alternating layers and a portion of the layer 360, and may expose the surface of the layer 360 that the portion of the spacer 340 in the region 370-b is formed on.

The material arrangement 300-b may include a spacer 340 (e.g., an oxide spacer). The spacer 340 may be formed using the dielectric material 310 (e.g., an oxide material). Additionally, or alternatively, the spacer 340 may be formed on exposed surfaces of the material arrangement 300-b. For example, a trench (e.g., a pier) may be formed through a portion of the material arrangement and the spacer 340 may be formed on surfaces exposed by the formation of the trench. The spacer 340 may be formed on sidewalls (e.g., surfaces extending along the z-direction and the x-direction) of the layer 355, sidewalls of the layer 365, sidewalls of the stack of alternating layers 355, and sidewalls of the layer 360. Additionally, or alternatively, the spacer 340 may be formed on top surfaces (e.g., surfaces extending along the y-direction and the x-direction) of the layer 355 and the layer 360.

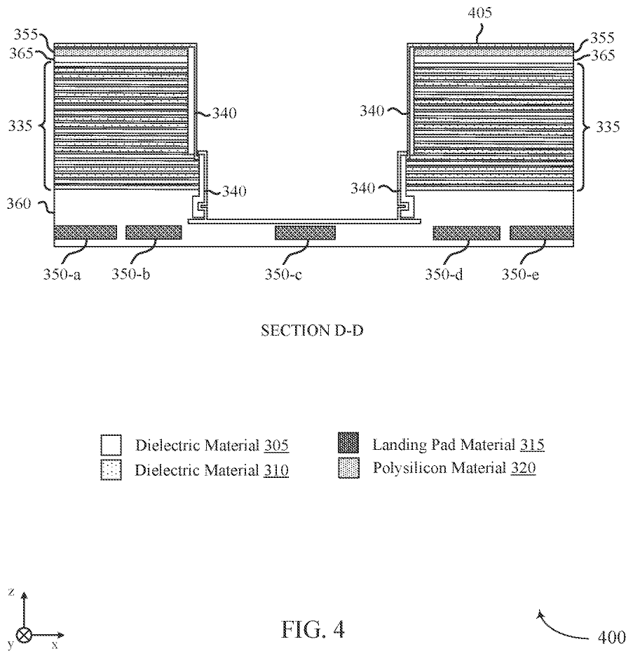

FIG. 4 shows an example of a material arrangement 400 that supports contact formation for a memory device in accordance with examples as disclosed herein. In some cases, the material arrangement 400 may be an example of one or more aspects of the system 100. For example, the material arrangement 400 may illustrate a section view (e.g., section D-D of FIG. 3A) of one or more aspects of a memory device 130, as described with reference to FIG. 1. In some cases, the material arrangement 400 may be an example of a word line contact staircase of a memory device 130 and may illustrate one or more processing operations used to form the word line contact staircase. For example, the material arrangement 400 may illustrate one or more processing operations performed subsequently to the one or more processing operations described with reference to FIGS. 3A and 3B. The material arrangement 400 may include materials and layers, which may be examples of materials and layers described with reference to FIGS. 3A and 3B. For example, the material arrangement 400 may include a layer 360, which may be an example of a layer 360 as described with reference to FIG. 3B. The material arrangement 400 may also include spacers 340, landing pads 350, a stack of alternating layers 335, layers 365, and layers 355, which may respectively be examples of spacers 340, landing pads 350, the stack of alternating layers 335, layers 365, and layers 355 as described with reference to FIG. 3B.

Forming the material arrangement 400 may include performing one or more processing steps subsequently to the one or more processing steps described with reference to FIG. 3B. For example, forming the material arrangement 400 may include removing a portion of a spacer 340 (e.g., selectively etching the spacer 340), which may expose a surface of an interconnect layer 345. For example, removing the portion of the spacer 340 may expose a top surface of the interconnect layer 345 with respect to the z-direction. In some cases, forming the material arrangement 400 may include removing a portion of the interconnect layer 345. The portion of the spacer 340 and the portion of the interconnect layer 345 may be removed using an etching operation. In some cases, the portion of the spacer 340 and the portion of the interconnect layer 345 may be removed for subsequent formation of the layer 405.

In some cases, the layer 405 (e.g., a sacrificial layer for subsequent formation of one or more word line contact layers) may be formed (e.g., deposited) on one or more surfaces of the material arrangement 400. For example, a layer 405 may have one or more portions extending along the z-direction and one or more portions extending along the x-direction. Additionally, or alternatively, a layer 405 may be formed on surfaces of the layer 360, surfaces of spacers 340, surfaces of the dielectric material 305, and surfaces of the dielectric material 310. A layer 405 may be formed using the dielectric material 310 (e.g., a nitride material). A layer 405 may be utilized for subsequent formation of word line contacts or other circuitry associated with the operation of word lines.

In some cases, forming the material arrangement 400 may include etching (e.g., selectively etching specific materials, selectively etching in specific locations, or both) spacers 340 to expose one or more layers of the stack of alternating layers 335 (e.g., to expose a surface of one or more nitride layers). In such cases, etching spacers 340 may enable a layer 405 to be formed in contact with a respective layer of the dielectric material 310 (e.g., a respective nitride layer). In some cases, one or more layers of the dielectric material 310 may also be etched (e.g., selectively) to enable the layer 405 to be formed in contact with respective layers of the dielectric material 310. Although the material arrangement 400 shows an illustrate example of the layer 405 formed in contact with a respective layer of the dielectric material 310, the layer 405 may be formed in contact with multiple layers of the dielectric material 310.

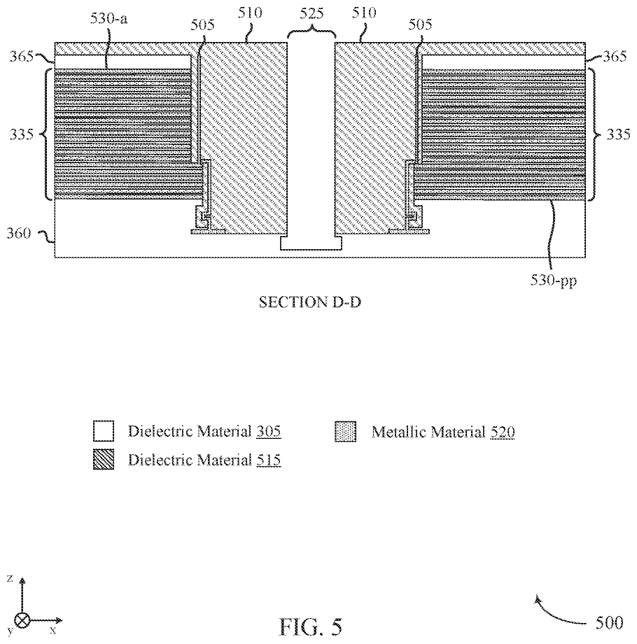

FIG. 5 shows an example of a material arrangement 500 that supports contact formation for a memory device in accordance with examples as disclosed herein. In some cases, the material arrangement 500 may be an example of one or more aspects of the system 100. For example, the material arrangement 500 may illustrate a section view (e.g., section D-D of FIG. 3A) of one or more aspects of a memory device 130, as described with reference to FIG. 1. In some cases, the material arrangement 500 may be an example of a word line contact staircase of a memory device 130 and may illustrate one or more processing operations used to form the word line contact staircase. For example, the material arrangement 500 may illustrate one or more processing operations performed subsequently to the one or more processing operations described with reference to FIG. 4. The material arrangement 500 may include materials and layers, which may be examples of materials and layers described with reference to FIGS. 3A-4. For example, the material arrangement 500 may include a layer 360, which may be an example of a layer 360 as described with reference to FIGS. 3A-4. The material arrangement 500 may also include a stack of alternating layers 335 and layers 365, which may respectively be examples of the stack of alternating layers 335 and layers 365 as described with reference to FIGS. 3A-4.

In some cases, forming the material arrangement 500 may include removing the layer 355 and at least a portion of the spacer 340 (e.g., a portion of the spacer 340 above the layer 355). In some cases, a planarization operation (e.g., a chemical mechanical planarization (CMP) operation) may be performed to removing the layer 355 and at least the portion of the spacer 340. may include forming a portion 510 using the dielectric material 515. For example, forming the portion 510 may include filling a pier area (e.g., a trench) with the dielectric material 515 (e.g., an oxide material) and performing a planarizing operation on the portion 510 (e.g., planarizing a top surface of the portion 510 with respect to the z-direction). In some cases, forming the material arrangement 500 may include removing the layers 355, as described with reference to FIG. 4. Removing the layers 355 may include performing a planarization operation. In some cases, the portion 510 may be formed in a multi-step process. For example, a first section (e.g., portion) of the portion 510 may be deposited in a pier area and a planarization operation may be performed on the first section. A second section of the portion 510 may then be deposited above (e.g., on top of) the first section and a planarization operation may be performed on the second section. In some cases, a trench 525 (e.g., a cell and replacement gate opening) may be formed through the portion 510. The trench 525 may also extend through at least a portion of the layer 360. In some cases, forming the trench 525 may include a patterning operation, an etching operation, or both.

Forming the material arrangement 500 may also include performing a metallization step. For example, the material arrangement 500 may include word lines 530 (e.g., word line 530-a through word line 530-pp) and word line contact portions 505 which may be formed using the metallic material 520 during a same step (e.g., concurrently). In some cases, word lines 530 may be formed in place of layers of the stack of alternating layers 335 (e.g., nitride layers). Additionally, or alternatively, word line contact portions 505 may be formed in place of layers 405. For example, nitride layers of the stack of alternating layers 335 and layers 405 may be exhumed prior to formation of word lines 530 and word line contact portions 505. In some cases, word lines 530 and word line contact portions 505 may be formed in a same step (e.g., concurrently) using the metallic material 520.

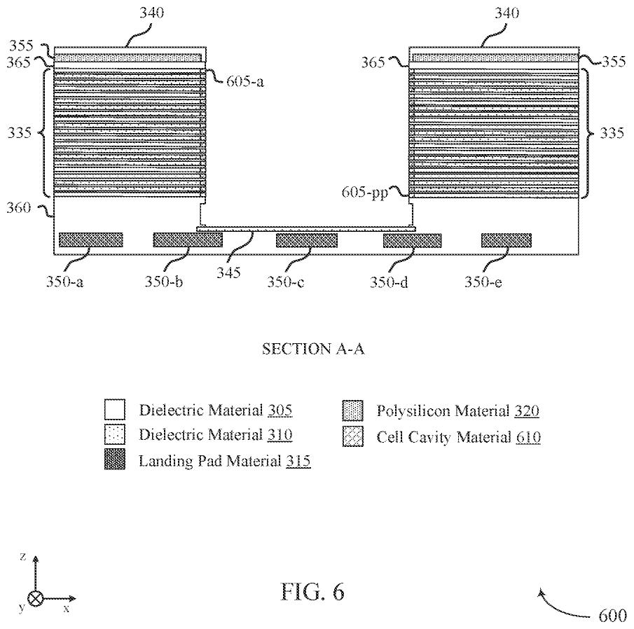

FIG. 6 shows an example of a material arrangement 600 that supports contact formation for a memory device in accordance with examples as disclosed herein. In some cases, the material arrangement 600 may be an example of one or more aspects of the system 100. For example, the material arrangement 600 may illustrate a section view (e.g., section A-A) of one or more aspects of a memory device 130, as described with reference to FIG. 1. In some cases, the material arrangement 600 may be an example of an array area of a memory device 130 and may illustrate one or more processing operations used to form the array area. The material arrangement 600 may show a different view of one or more aspects of the material arrangement 300-b, the material arrangement 400, or the material arrangement 500. Accordingly, the material arrangement 600 may include materials and layers, which may be examples of materials and layers described with reference to FIGS. 3A-5, but formed in different locations. For example, the material arrangement 600 may include one or more aspects of the material arrangement 300-b as described with reference to FIG. 3B.

In some cases, one or more layers may be formed above (e.g., with respect to the z-direction) the stack of alternating layers 335. For example, a layer 365 may be formed above the stack of alternating layers 335. The layer 365 may be formed using the dielectric material 305 (e.g., an oxide material). In some cases, a layer 355 may be formed above the layer 365. The layer 355 may be formed using a polysilicon material 320. The polysilicon material 320 may be an example of a sacrificial material. In some cases, a spacer 340 (e.g., an oxide spacer) may be formed above the layer 355 using the dielectric material 310 (e.g., an oxide material). For example, the spacer 340 may initially be formed on one or more surfaces of the material arrangement 600 (e.g., as shown in FIG. 3B). In such cases, one or more cavities may be formed extending through the stack of alternating layers 335 and a portion of the layer 360, and the spacer 340 may be formed in the one or more cavities. In some cases, a portion of the spacer 340, as shown in FIG. 3B, may be removed, resulting in the geometry of the spacer 340 as shown in FIG. 6.

The material arrangement 600 may also include a plurality of portions 605 (e.g., portion 605-a through portion 605-pp, cell cavity sacrificial material portions). Each portion 605 of the plurality of portions 605 may be formed using a cell cavity material 610 (e.g., borophosphosilicate glass (BSPG), carbon nitride). In some cases, forming the material arrangement 600 may include removing a pier etch stop layer and recessing respective portions of respective layers of the stack of alternating layers 335 (e.g., nitride layers). The respective portions may be recessed using one or more etching operations, which may form cell formation cavities. In a subsequent processing step, cell formation cavities may be filled with the cell cavity material 610, forming portions 605. In some cases, the portions 605 may be subsequently removed for formation of memory cells. In some cases, forming the material arrangement 600 may include removing some portions of the dielectric material 305 for formation of cell formation cavities (e.g., if more thickness is needed for portions 605, portions of an oxide material in the stack of alternating layers 335 may be thinned).

In some cases, portions 605 may be selectively etchable. For example, portions 605 may be etched without etching or otherwise interfering with other components of the material arrangement 600. In some cases, portions 605 may be etchable without etching or otherwise interfering with bit line sacrificial rings, as described in further detail with reference to FIG. 8A. Additionally, or alternatively, portions 605 may not be etched during a nitride exhuming operation (e.g., for replacement gate formation, an exhuming operation to remove a dielectric material 310). In some cases, forming the material arrangement 600 may include removing (e.g., etching) a portion of the layer 360 above the interconnect layer 345. For example, a portion of the layer 360 may be removed such that a surface (e.g., a portion of a surface) of the interconnect layer 345 is exposed.

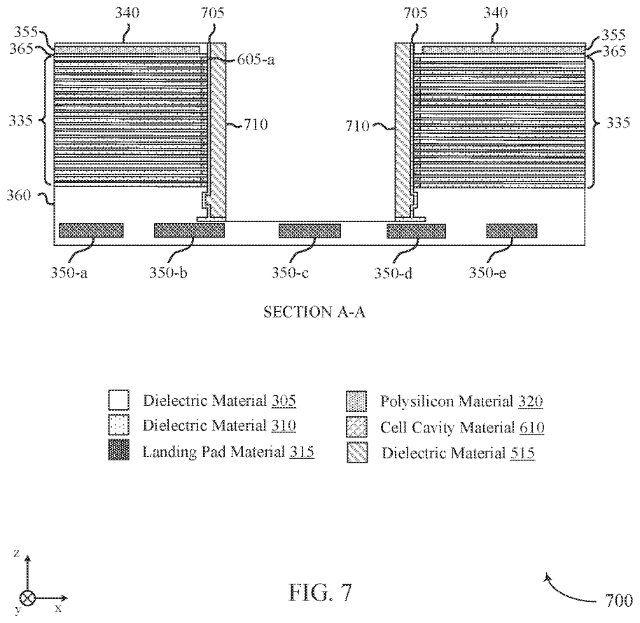

FIG. 7 shows an example of a material arrangement 700 that supports contact formation for a memory device in accordance with examples as disclosed herein. In some cases, the material arrangement 700 may be an example of one or more aspects of the system 100. For example, the material arrangement 700 may illustrate a section view (e.g., section A-A) of one or more aspects of a memory device 130, as described with reference to FIG. 1. In some cases, the material arrangement 700 may be an example of an array area of a memory device 130 and may illustrate one or more processing operations used to form the array area. The material arrangement 700 may show a view of the material arrangement 600 after one or more processing operations have been performed. Accordingly, the material arrangement 700 may include materials and layers, which may be examples of materials and layers described with reference to FIGS. 3A-6. For example, the material arrangement 700 may include a layer 360, which may be an example of a layer 360 as described with reference to FIGS. 3-6. The material arrangement 700 may also include landing pads 350, a stack of alternating layers 335, layers 365, layers 355, portions 605, and spacers 340, which may respectively be examples of landing pads 350, the stack of alternating layers 335, layers 365, layers 355, portions 605 and spacers 340 as described with reference to FIGS. 3-6.

Forming the material arrangement 700 may include removing a portion of the interconnect layer 345, as described with reference to FIG. 6. For example, an etching operation may be performed to remove the portion of the interconnect layer 345. The layer 705 may then be formed. In some cases, forming the layer 705 may include depositing the dielectric material 310 on surfaces of the spacers 340, sidewalls of layers in the stack of alternating layers 335, sidewalls of portions 605, sidewalls of the layer 360, and a surface of the layer 360. Portions of the dielectric material 310 may then be removed (e.g., etched) to form the layers 705, as shown. For example, portions of the dielectric material 310 formed on a surface of the spacers 340 and portions of the dielectric material 310 formed on a surface of the layer 360 may be removed. As described herein, a layer 705 may have one or more portions extending along the z-direction and one or more portions extending along the x-direction. Additionally, or alternatively, a layer 705 may be formed on surfaces of the layer 360, surfaces of layers of the dielectric material 305, surfaces of portions 605, surfaces of the spacer 340, and surfaces of the layer 365. The layers 705 may be formed using the dielectric material 310 (e.g., a nitride material). The layers 705 may be utilized for subsequent formation of bit lines.

In some cases, the material arrangement 700 may include one or more spacers 710 (e.g., one or more oxide spacers). The one or more spacers 710 may be formed (e.g., deposited) on exposed surfaces of the layers 705. The one or more spacers 710 may be formed using a dielectric material 515 (e.g., an oxide material). In some cases, the dielectric material 515 and the dielectric material 305 may be a same material. In some cases, the one or more spacers 710 may be formed (e.g., deposited) to protect word line contacts (e.g., ends of word line contacts). In some cases, forming the material arrangement 700 may include selectively etching the one or more spacers 710.

FIG. 8A shows an example of a process 800-a that supports contact formation for a memory device in accordance with examples as disclosed herein. In some cases, the process 800-a may illustrate one or more aspects of the system 100. For example, the process 800-a may include steps 835 which may be utilized for the formation of one or more aspects of the system 100, such as contact portions 805 and an interconnect conductor 840. In some cases, the contact portions 805 may be utilized for coupling bit lines, as described in further detail with reference to FIG. 9B, with circuitry located below a substrate of a memory device 130. The contact portions 805 may also be utilized for coupling word lines, as described in further detail with reference to FIGS. 6 and 9B, with circuitry located below a substrate of the memory device 130.

The process 800-a may include a step 835-a. The step 835-a may include forming a cavity 845 in the layer 360. In some cases, the cavity 845 may extend through the interconnect layer 345, as described with reference to FIGS. 3, 4, 6, and 7. In some cases, the cavity 845 may have a cylindrical shape with height parallel to the z-direction. The process 800-a may also include a step 835-b. The step 835-b may include removing (e.g., recessing, exhuming) portions 850 of the interconnect layer 345. The portions 850 of the interconnect layer 345 may be removed via the cavity 845 (e.g., using a wet etch). The process 800-a may also include a step 835-c. The step 835-c may include forming a sacrificial ring 830 (e.g., via the cavity 845). That is, the cavity 845 may be used to access portions of the interconnect layer 345 for formation of the sacrificial ring 830. The sacrificial ring 830 may have a cylindrical shape and may be formed around the cavity 845. The sacrificial ring 830 may be formed using the ring material 825 (e.g., using BPSG, using carbon nitride), which may be a different material than the dielectric material 310 used as a sacrificial material for the interconnect layer 345. A contact portion 805 may then be formed in the cavity. The contact portion 805 may be formed using a metallic material 520 (e.g., tungsten). As described herein, the sacrificial ring 830 may isolate the contact portion 805 from an etching solution used to subsequently etch the interconnect layer 345 and form the exhumed portion 810, as shown in step 835-c. For example, the step 835-c may correspond to steps performed to exhume the dielectric material 310 as discussed with reference to FIGS. 5 and 8B. The process 800-a may include a step 835-d. The step 835-d may include removing the sacrificial ring 830 (e.g., via an etching operation that selectively removes the sacrificial ring 830 without removing or otherwise contaminating the contact portion 805). Once the sacrificial ring 830 is removed, an interconnect conductor 840 may be formed in place of the exhumed portion 810 (e.g., the exhumed portion of the interconnect layer 345). The step 835-d may correspond to operations used to form the word lines 530, word line contact portions 505, and bit lines 910 as discussed with reference to FIGS. 5 and 9C. The interconnect conductor 840 may be formed using the metallic material 520 and may couple one or more contact portions 805 with one or more word lines, one or more bit lines, or both. In some cases, a contact portion 805 may be coupled with a word line via a word line contact portion 505, as described with reference to FIG. 5. In some other cases, a contact portion 805 may be coupled directly with a bit line (e.g., a bit line 910 as described with reference to FIGS. 9A and 9C).

FIG. 8B shows an example of a material arrangement 800-b that supports contact formation for a memory device in accordance with examples as disclosed herein. In some cases, the material arrangement 800-b may be an example of one or more aspects of the system 100. For example, the material arrangement 800-b may illustrate a section view (e.g., section B-B) of one or more aspects of a memory device 130, as described with reference to FIG. 1. In some cases, the material arrangement 800-b may be an example of an array area of a memory device 130 and may illustrate one or more processing operations used to form the array area. The material arrangement 800-b may include materials and layers, which may be examples of materials and layers described with reference to FIGS. 3A-7.

The material arrangement 800-b may be formed by performing one or more processing operations on the material arrangement 700. For example, a pier area of the material arrangement 700 may be filled with the dielectric material 515 (e.g., an oxide material). Portions 605 and replacement gate openings (not shown) may then be formed (e.g., via a patterning operation, via an etching operation, or both). Forming the material arrangement 800-b may also include removing landing pads 350 from the layer 360. The layer 360 may be an example of the layer 360 as described with reference to FIG. 8A. Although not shown in FIG. 8B, the layer 360 may include contact portions 805 and interconnect conductors 840, as described with reference to FIG. 8A.

The material arrangement 800-b may include trenches 820 (e.g., openings, cavities, cell and replacement gate openings). Trenches 820 (e.g., trench 820-a, trench 820-b, trench 820-c) may be utilized for forming portions of the material arrangement 800-b. In some cases, trenches 820 may be filled with a dielectric material 515 (e.g., an oxide material). The dielectric material 515 may be a same material as the dielectric material 305. In some cases, forming the material arrangement 800-b may include forming exhumed portions 810. For example, portions of the material arrangement 800-b that were previously formed using the dielectric material 310 (e.g., word line sacrificial portions, bit line sacrificial portions) may be exhumed.

FIG. 9A shows an example of a process 900-a that supports contact formation for a memory device in accordance with examples as disclosed herein. In some cases, the process 900-a may illustrate one or more aspects of the system 100. For example, the process 900-a may include steps 955 (e.g., a step 955-a, a step 955-b) which may be utilized for the formation of one or more aspects of the system 100, such as electrodes 920 and a memory cell 915. In some cases, the process 900-a may illustrate views (e.g., memory cell views, front views) of one or more aspects of a memory device 130, as described with reference to FIG. 1. In some cases, the process 900-a may illustrate a word line 905 (e.g., a word line conductor), a bit line 910 (e.g., a bit line conductor), a memory cell 915, a portion 605, and one or more electrodes 920. As described herein, the bit line 910 may be operable to transfer current to and from the memory cell 915 (e.g., via electrodes 920) based on a current applied to the word line 905. For example, access operations, such as read and write operations may be performed by transferring current via a bit line 910.

The process 900-a may include a step 955-a. The step 955-a may include forming one or more electrodes 920 using the electrode material 945. The one or more electrodes 920 may be formed prior to formation of the word line 905 and the bit line 910. For example, the one or more electrodes 920 may be formed in exhumed portions 810, as described with reference to FIG. 8B, prior to the formation of word lines 905 and bit lines 910 in respective exhumed portions 810. Such a formation process may enable the one or more electrodes 920 to be etched (e.g., via a wet etching process) prior to formation of the memory cell 915, which may prevent the etching process from adversely affecting or otherwise damaging the cell material 950. In some cases, the portion 605 may be recessed to form a cavity for formation of the memory cell 915. For example, the portion 605 may be recessed along the y-direction, such that the memory cell 915 may be formed as shown in step 955-b (e.g., in contact with electrodes 920). In such cases, the portion 605 may be recessed subsequently to step 955-a.

The process 900-a may include a step 955-b, which may be performed subsequently to the step 955-a. The step 955-b may include forming the memory cell 915. The memory cell 915 may be formed in the cavity formed by recessing the cell cavity material 610 (e.g., via a slit formed in the stack of alternating layers in the xz-plane). For example, a memory material may be deposited in the slit and the cavities and be etched back from the slit to leave portions of the memory material in each cavity. The process 900-a may provide an example of a formation process for forming one or more memory cells 915 of a memory device 130. Although the process 900-a shows a single memory cell 915, techniques and architectures described herein may be applied to any quantity of memory cells 915 of a memory device 130. In some cases, the word line 905 and the bit line 910 may be formed in place of removed portions of a dielectric material 310, as described with reference to FIGS. 3-7. In some cases, the word line 905 and the bit line 910 may be formed concurrently (e.g., in a same processing operation), which may improve speed and accuracy of the formation process. Additionally, or alternatively, the word line 905 and the bit line 910 may be formed using the metallic material 520 (e.g., tungsten, molybdenum, or a combination thereof). The one or more electrodes 920 may be formed using the electrode material 945 (e.g., carbon) and the memory cell 915 may be formed using the cell material 950. In some cases, the one or more electrodes 920 may be formed and subsequently shaped using a wet etching process.

FIG. 9B shows an example of a material arrangement 900-b that supports contact formation for a memory device in accordance with examples as disclosed herein. In some cases, the material arrangement 900-b may be an example of one or more aspects of the system 100. For example, the material arrangement 900-b may illustrate a section view (e.g., section E-E) of the material arrangement 900-c, as described with reference to FIG. 9C. The material arrangement 900-b may include memory cells 915 (e.g., a memory cell 915-a, a memory cell 915-b), which may be examples of a memory cell 915 as described with reference to FIG. 9A. The material arrangement 900-b may also include cell cavity portions 925 (e.g., a cell cavity portion 925-a, a cell cavity portion 925-b), dielectric portions 930 (e.g., a dielectric portion 930-a, a dielectric portion 930-b, a dielectric portion 930-c), and a cell seal portion 935.

Forming the material arrangement 900-b may include forming cavities for subsequent formation of memory cells 915. For example, an etching operation may be formed to remove portions the dielectric material 305. Memory cells 915 may then be formed in the cavities. In some cases, additional portions of the dielectric material 305 may be removed (e.g., via a wet etching operation), which may expose portions of cell cavity portions 925. Forming the material arrangement 900-b may also include removing portions of the cell cavity portions 925. In some cases, the cell seal material 940 may be formed in place of removed portions of the dielectric material 305 and removed portions of the cell cavity portions 925.

The cell seal portion 935 may be formed using a cell seal material 940. In some cases, a planarizing operation may be performed to planarize a surface of the cell scal portion 935. For example, a surface of the cell seal portion 935, such as a top surface with respect to the z-direction, may be planarized.

FIG. 9C shows an example of a material arrangement 900-c that supports contact formation for a memory device in accordance with examples as disclosed herein. In some cases, the material arrangement 900-c may be an example of one or more aspects of the system 100. For example, the material arrangement 900-c may illustrate a section view (e.g., section B-B) of one or more aspects of a memory device 130, as described with reference to FIG. 1. In some cases, the material arrangement 900-c may be an example of an array area of a memory device 130 and may illustrate one or more processing operations used to form the array area. The material arrangement 900-c may include materials and layers, which may be examples of materials and layers described with reference to FIGS. 3A-9B. For example, the material arrangement 900-c may include a layer 360, which may be an example of a layer 360 as described with reference to FIGS. 3-9B. The material arrangement 900-c may also include word lines 905 (e.g., beginning with word line 905-a) and bit lines 910 (e.g., beginning with bit line 910-a), which may be examples of word lines 905 and bit lines 910 as described with reference to FIG. 9A. In some cases, the material arrangement 900-c may also include trenches 820, which may be examples of trenches 820 as described with reference to FIG. 8B.

In some cases, forming the material arrangement 900-c may include forming bit lines 910 and word lines 905 in place of exhumed portions 810, as described with reference to FIG. 8B. In such cases, bit lines 910 and word lines 905 may be formed using a metallic material 520 (e.g., tungsten, titanium, titanium nitride, molybdenum, or any combination thereof). Bit lines 910 and word lines 905 may be formed using a chemical vapor deposition (CVD) or atomic layer deposition (ALD) process. In some cases, forming bit lines 910 and word lines 905 may include an etching operation to isolate word lines 905 from bit lines 910 (e.g., word lines 905, bit lines 910, or both, may be etched back from a slit). Additionally, or alternatively, bit lines 910 and word lines 905 may be formed during a same processing step (e.g., concurrently). Forming bit lines 910 and word lines 905 during a same processing step may improve processing accuracy and processing speed for the memory device manufacturing operation.

FIG. 10 shows a flowchart illustrating a method 1000 that supports contact formation for a memory device in accordance with examples as disclosed herein. The operations of method 1000 may be implemented by a manufacturing system or its components as described herein. For example, the operations of method 1000 may be performed by a manufacturing system as described with reference to FIGS. 1 through 9. In some examples, a manufacturing system may execute a set of instructions to control the functional elements of the device to perform the described functions. Additionally, or alternatively, the manufacturing system may perform aspects of the described functions using special-purpose hardware.

At 1005, the method may include forming, in a first dielectric material of a substrate, a first layer including a second dielectric material, the first layer elongated along a first direction parallel to a surface of the substrate and a second direction parallel to the surface of the substrate. The operations of 1005 may be performed in accordance with examples as disclosed herein. In some examples, aspects of the operations of 1005 may be performed by a manufacturing system as described with reference to FIGS. 1 through 9.

At 1010, the method may include forming a first plurality of cavities through at least a portion of the first dielectric material and through the first layer including the second dielectric material. The operations of 1010 may be performed in accordance with examples as disclosed herein. In some examples, aspects of the operations of 1010 may be performed by a manufacturing system as described with reference to FIGS. 1 through 9.

At 1015, the method may include recessing, via the first plurality of cavities, a first plurality of portions of the first layer, where the recessing forms a second plurality of cavities in the first layer. The operations of 1015 may be performed in accordance with examples as disclosed herein. In some examples, aspects of the operations of 1015 may be performed by a manufacturing system as described with reference to FIGS. 1 through 9.

At 1020, the method may include forming, in one or more cavities of the second plurality of cavities, respective portions of a third dielectric material. The operations of 1020 may be performed in accordance with examples as disclosed herein. In some examples, aspects of the operations of 1020 may be performed a manufacturing system as described with reference to FIGS. 1 through 9.

At 1025, the method may include forming, in the first plurality of cavities, a plurality of contact portions, each contact portion of the plurality of contact portions including a metallic material. The operations of 1025 may be performed in accordance with examples as disclosed herein. In some examples, aspects of the operations of 1025 may be performed by a manufacturing system as described with reference to FIGS. 1 through 9. At 1030, the method may include forming, above the plurality of contact portions, a stack of alternating tiers of the first dielectric material and the second dielectric material, where a trench extends through the stack of alternating tiers. The operations of 1030 may be performed in accordance with examples as disclosed herein. In some examples, aspects of the operations of 1030 may be performed by a manufacturing system as described with reference to FIGS. 1 through 9.

At 1035, the method may include forming, in the trench, a segment extending along a third direction orthogonal to the surface of the substrate and including the second dielectric material. The operations of 1035 may be performed in accordance with examples as disclosed herein. In some examples, aspects of the operations of 1035 may be performed by a manufacturing system as described with reference to FIGS. 1 through 9. At 1040, the method may include removing the second dielectric material from the segment extending along the third direction, the first layer, and a plurality of tiers of the stack of alternating tiers. The operations of 1040 may be performed in accordance with examples as disclosed herein. In some examples, aspects of the operations of 1040 may be performed by a manufacturing system as described with reference to FIGS. 1 through 9.

At 1045, the method may include removing the respective portions of the third dielectric material based at least in part on removing the segment extending along the third direction. The operations of 1045 may be performed in accordance with examples as disclosed herein. In some examples, aspects of the operations of 1045 may be performed by a manufacturing system as described with reference to FIGS. 1 through 9.

In some examples, an apparatus as described herein may perform a method or methods, such as the method 1000. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming, in a first dielectric material of a substrate, a first layer including a second dielectric material, the first layer elongated along a first direction parallel to a surface of the substrate and a second direction parallel to the surface of the substrate; forming a first plurality of cavities through at least a portion of the first dielectric material and through the first layer including the second dielectric material; recessing, via the first plurality of cavities, a first plurality of portions of the first layer, where the recessing forms a second plurality of cavities in the first layer; forming, in one or more cavities of the second plurality of cavities, respective portions of a third dielectric material; forming, in the first plurality of cavities, a plurality of contact portions, each contact portion of the plurality of contact portions including a metallic material; forming, above the plurality of contact portions, a stack of alternating tiers of the first dielectric material and the second dielectric material, where a trench extends through the stack of alternating tiers; forming, in the trench, a segment extending along a third direction orthogonal to the surface of the substrate and including the second dielectric material; removing the second dielectric material from the segment extending along the third direction, the first layer, and a plurality of tiers of the stack of alternating tiers; and removing the respective portions of the third dielectric material based at least in part on removing the segment extending along the third direction.

Aspect 2: The method, apparatus, or non-transitory computer-readable medium of aspect 1, where the second dielectric material of the segment extending along the third direction, the first layer, and the plurality of tiers of the stack of alternating tiers are removed during a first etching operation and the respective portions of the third dielectric material are removed during a second etching operation that occurs after the first etching operation.

Aspect 3: The method, apparatus, or non-transitory computer-readable medium of any of aspects 1 through 2, where the segment extending along the third direction is in contact with the first layer including the second dielectric material.

Aspect 4: The method, apparatus, or non-transitory computer-readable medium of any of aspects 1 through 3, where each cavity of the second plurality of cavities surrounds at least a portion of a respective cavity of the first plurality of cavities.

Aspect 5: The method, apparatus, or non-transitory computer-readable medium of any of aspects 1 through 4, where each cavity of the second plurality of cavities is in contact with a respective cavity of the first plurality of cavities.

Aspect 6: The method, apparatus, or non-transitory computer-readable medium of any of aspects 1 through 5, where the first layer and one or more cavities of the first plurality of cavities intersect and recessing the first plurality of portions of the first layer isolates the first layer from the one or more cavities.

Aspect 7: The method, apparatus, or non-transitory computer-readable medium of any of aspects 1 through 6, where each cavity of the first plurality of cavities is formed in a cylindrical shape having a longitudinal axis parallel with the third direction.

Aspect 8: The method, apparatus, or non-transitory computer-readable medium of any of aspects 1 through 7, where each contact portion of the plurality of contact portions includes a cylindrical shape elongated along the third direction.

FIG. 11 shows a flowchart illustrating a method 1100 that supports contact formation for a memory device in accordance with examples as disclosed herein. The operations of method 1100 may be implemented by a manufacturing system or its components as described herein. For example, the operations of method 1100 may be performed by a manufacturing system as described with reference to FIGS. 1 through 9. In some examples, a manufacturing system may execute a set of instructions to control the functional elements of the device to perform the described functions. Additionally, or alternatively, the manufacturing system may perform aspects of the described functions using special-purpose hardware.

At 1105, the method may include forming, in a first dielectric material of a substrate, a layer including a second dielectric material. The operations of 1105 may be performed in accordance with examples as disclosed herein. In some examples, aspects of the operations of 1105 may be performed by a manufacturing system as described with reference to FIGS. 1 through 9.

At 1110, the method may include forming, above the layer including the second dielectric material, a stack of tiers of the first dielectric material that alternate with the second dielectric material, where the stack of tiers includes a first plurality of tiers including the first dielectric material and a second plurality of tiers including the second dielectric material. The operations of 1110 may be performed in accordance with examples as disclosed herein. In some examples, aspects of the operations of 1110 may be performed by a manufacturing system as described with reference to FIGS. 1 through 9.

At 1115, the method may include forming a first cavity in the stack of tiers, the first cavity having a first dimension below a first tier of the second plurality of tiers along a direction orthogonal to the substrate and a second dimension greater than the first dimension above the first tier along the direction. The operations of 1115 may be performed in accordance with examples as disclosed herein. In some examples, aspects of the operations of 1115 may be performed by a manufacturing system as described with reference to FIGS. 1 through 9.

At 1120, the method may include forming, in the first cavity, a first segment including the second dielectric material, where the first segment is in contact with a first tier of the second plurality of tiers. The operations of 1120 may be performed in accordance with examples as disclosed herein. In some examples, aspects of the operations of 1120 may be performed by a manufacturing system as described with reference to FIGS. 1 through 9.

At 1125, the method may include forming, in the first cavity, a second segment including the second dielectric material, where the second segment is in contact with the first segment and the layer including the second dielectric material. The operations of 1125 may be performed in accordance with examples as disclosed herein. In some examples, aspects of the operations of 1125 may be performed by a manufacturing system as described with reference to FIGS. 1 through 9.

At 1130, the method may include removing the second dielectric material from the first segment, the second segment, and each tier of the second plurality of tiers. The operations of 1130 may be performed in accordance with examples as disclosed herein. In some examples, aspects of the operations of 1130 may be performed by a manufacturing system as described with reference to FIGS. 1 through 9.

At 1135, the method may include forming a word line in place of a first removed tier of the second plurality of tiers. The operations of 1135 may be performed in accordance with examples as disclosed herein. In some examples, aspects of the operations of 1135 may be performed a manufacturing system as described with reference to FIGS. 1 through 9.

At 1140, the method may include forming a word line contact in place of the first segment and the second segment. The operations of 1140 may be performed in accordance with examples as disclosed herein. In some examples, aspects of the operations of 1140 may be performed by a manufacturing system as described with reference to FIGS. 1 through 9.

In some examples, an apparatus as described herein may perform a method or methods, such as the method 1100. The apparatus may include features, circuitry, logic, means, or instructions (e.g., a non-transitory computer-readable medium storing instructions executable by a processor), or any combination thereof for performing the following aspects of the present disclosure:

Aspect 9: A method, apparatus, or non-transitory computer-readable medium including operations, features, circuitry, logic, means, or instructions, or any combination thereof for forming, in a first dielectric material of a substrate, a layer including a second dielectric material; forming, above the layer including the second dielectric material, a stack of tiers of the first dielectric material that alternate with the second dielectric material, where the stack of tiers includes a first plurality of tiers including the first dielectric material and a second plurality of tiers including the second dielectric material; forming a first cavity in the stack of tiers, the first cavity having a first dimension below a first tier of the second plurality of tiers along a direction orthogonal to the substrate and a second dimension greater than the first dimension above the first tier along the direction; forming, in the first cavity, a first segment including the second dielectric material, where the first segment is in contact with a first tier of the second plurality of tiers; forming, in the first cavity, a second segment including the second dielectric material, where the second segment is in contact with the first segment and the layer including the second dielectric material; removing the second dielectric material from the first segment, the second segment, and each tier of the second plurality of tiers; forming a word line in place of a first removed tier of the second plurality of tiers; and forming a word line contact in place of the first segment and the second segment.

Aspect 10: The method, apparatus, or non-transitory computer-readable medium of aspect 9, where the word line contact and the word line are formed in a same processing step and include a same metallic material.

Aspect 11: The method, apparatus, or non-transitory computer-readable medium of any of aspects 9 through 10, where a region of the stack of tiers includes a plurality of sub-regions and prior to forming the first and second segments, each sub-region of the plurality of sub-regions exposes a portion of a surface of a respective tier of the second plurality of tiers.

Aspect 12: The method, apparatus, or non-transitory computer-readable medium of aspect 11, where removing the first segment, the second segment, and each tier of the second plurality of tiers includes forming respective second cavities between each sub-region and exhuming the second dielectric material from the first segment, the second segment, and each tier of the second plurality of tiers via the respective second cavities and forming the word line and the word line contact includes depositing, via the respective second cavities, a conductive material within voids formed by the exhuming of the second dielectric material from the first segment the second segment, and each tier of the second plurality of tiers.

Aspect 13: The method, apparatus, or non-transitory computer-readable medium of any of aspects 9 through 12, further including operations, features, circuitry, logic, means, or instructions, or any combination thereof for depositing, prior to forming the first segment and the second segment, a third dielectric material on sidewalls of the first cavity.

Aspect 14: The method, apparatus, or non-transitory computer-readable medium of any of aspects 9 through 13, where the first segment extends from the first tier of the second plurality of tiers along a direction orthogonal to a surface of the substrate and towards a top surface of the stack of tiers.

Aspect 15: The method, apparatus, or non-transitory computer-readable medium of any of aspects 9 through 14, where the second segment extends from the first tier of the second plurality of tiers along a direction orthogonal to a surface of the substrate and towards the substrate.

Aspect 16: The method, apparatus, or non-transitory computer-readable medium of any of aspects 9 through 15, further including operations, features, circuitry, logic, means, or instructions, or any combination thereof for forming a second word line in place of a second removed tier of the second plurality of tiers and forming a second word line contact in place of a third segment including the second dielectric material, where the second word line contact is offset from the word line contact along a direction parallel to a surface of the substrate.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 17: An apparatus including: a memory die including a substrate and a first layer formed above the substrate, the first layer including a dielectric material; a plurality of word lines above the first layer and formed in a stack of layers of a first material that alternate with a second material, where a region of the stack of layers includes a plurality of sub-regions, and where each sub-region of the plurality of sub-regions exposes a portion of a surface of a respective word line; a first plurality of contact portions including the first material, each contact portion of the first plurality of contact portions formed on a first surface of the first layer, where the first plurality of contact portions are below the plurality of word lines and extend along a first direction parallel with a surface of the substrate; and a second plurality of contact portions including the first material, each contact portion of the second plurality of contact portions coupling the respective word line with a respective contact portion of the first plurality of contact portions, where each contact portion of the second plurality of contact portions has a first segment that extends along a second direction perpendicular to the surface of the substrate and a second segment that extends along the first direction and connects the exposed portion of the surface of the respective word line with the first segment.

Aspect 18: The apparatus of aspect 17, further including: a plurality of bit lines including the first material, where each bit line of the plurality of bit lines extends along the second direction, and where each bit line of the plurality of bit lines is formed in a same processing step as each word line of the plurality of word lines.

Aspect 19: The apparatus of aspect 18, further including: a plurality of memory cells, where each bit line of the plurality of bit lines is coupled with the plurality of memory cells.

Aspect 20: The apparatus of any of aspects 17 through 19, where each contact of the first plurality of contact portions, each contact of the second plurality of contact portions, and each word line of the plurality of word lines are formed in a same processing step.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, and/or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
forming, in a first dielectric material of a substrate, a first layer comprising a second dielectric material, the first layer elongated along a first direction parallel to a surface of the substrate and a second direction parallel to the surface of the substrate;
forming a first plurality of cavities through at least a portion of the first dielectric material and through the first layer comprising the second dielectric material;
recessing, via the first plurality of cavities, a first plurality of portions of the first layer, wherein the recessing forms a second plurality of cavities in the first layer;
forming, in one or more cavities of the second plurality of cavities, respective portions of a third dielectric material;
forming, in the first plurality of cavities, a plurality of contact portions, each contact portion of the plurality of contact portions comprising a metallic material;
forming, above the plurality of contact portions, a stack of alternating tiers of the first dielectric material and the second dielectric material, wherein a trench extends through the stack of alternating tiers;
forming, in the trench, a segment extending along a third direction orthogonal to the surface of the substrate and comprising the second dielectric material;
removing the second dielectric material from the segment extending along the third direction, the first layer, and a plurality of tiers of the stack of alternating tiers; and
removing the respective portions of the third dielectric material based at least in part on removing the segment extending along the third direction.

2. The method of claim 1, wherein:
the second dielectric material of the segment extending along the third direction, the first layer, and the plurality of tiers of the stack of alternating tiers are removed during a first etching operation, and
the respective portions of the third dielectric material are removed during a second etching operation that occurs after the first etching operation.

3. The method of claim 1, wherein the segment extending along the third direction is in contact with the first layer comprising the second dielectric material.

4. The method of claim 1, wherein each cavity of the second plurality of cavities surrounds at least a portion of a respective cavity of the first plurality of cavities.

5. The method of claim 1, wherein each cavity of the second plurality of cavities is in contact with a respective cavity of the first plurality of cavities.

6. The method of claim 1, wherein:
the first layer and one or more cavities of the first plurality of cavities intersect; and
recessing the first plurality of portions of the first layer isolates the first layer from the one or more cavities.

7. The method of claim 1, wherein each cavity of the first plurality of cavities is formed in a cylindrical shape having a longitudinal axis parallel with the third direction.

8. The method of claim 1, wherein each contact portion of the plurality of contact portions comprises a cylindrical shape elongated along the third direction.

9. An apparatus comprising:
a memory die comprising a substrate and a first layer formed above the substrate, the first layer comprising a dielectric material;
a plurality of word lines above the first layer and formed in a stack of layers of a first material that alternate with a second material, wherein a region of the stack of layers comprises a plurality of sub-regions, and wherein each sub-region of the plurality of sub-regions exposes a portion of a surface of a respective word line;
a first plurality of contact portions comprising the first material, each contact portion of the first plurality of contact portions formed on a first surface of the first layer, wherein the first plurality of contact portions are below the plurality of word lines and extend along a first direction parallel with a surface of the substrate; and
a second plurality of contact portions comprising the first material, each contact portion of the second plurality of contact portions coupling the respective word line with a respective contact portion of the first plurality of contact portions, wherein each contact portion of the second plurality of contact portions has a first segment that extends along a second direction perpendicular to the surface of the substrate and a second segment that extends along the first direction and connects the exposed portion of the surface of the respective word line with the first segment.

10. The apparatus of claim 9, further comprising:
a plurality of bit lines comprising the first material, wherein each bit line of the plurality of bit lines extends along the second direction, and wherein each bit line of the plurality of bit lines is formed in a same processing step as each word line of the plurality of word lines.

11. The apparatus of claim 10, further comprising:
a plurality of memory cells, wherein each bit line of the plurality of bit lines is coupled with the plurality of memory cells.

12. The apparatus of claim 9, wherein each contact of the first plurality of contact portions, each contact of the second plurality of contact portions, and each word line of the plurality of word lines are formed in a same processing step.

13. A method comprising,
forming, in a first dielectric material of a substrate, a layer comprising a second dielectric material;
forming, above the layer comprising the second dielectric material, a stack of tiers of the first dielectric material that alternate with the second dielectric material, wherein the stack of tiers comprises a first plurality of tiers comprising the first dielectric material and a second plurality of tiers comprising the second dielectric material;
forming a first cavity in the stack of tiers, the first cavity having a first dimension below a first tier of the second plurality of tiers along a direction orthogonal to the substrate and a second dimension greater than the first dimension above the first tier along the direction;
forming, in the first cavity, a first segment comprising the second dielectric material, wherein the first segment is in contact with the first tier of the second plurality of tiers;
forming, in the first cavity, a second segment comprising the second dielectric material, wherein the second segment is in contact with the first segment and the layer comprising the second dielectric material;
removing the second dielectric material from the first segment, the second segment, and each tier of the second plurality of tiers;
forming a word line in place of a first removed tier of the second plurality of tiers; and
forming a word line contact in place of the first segment and the second segment.

14. The method of claim 13, wherein the word line contact and the word line are formed in a same processing step and comprise a same metallic material.

15. The method of claim 13, wherein:
a region of the stack of tiers comprises a plurality of sub-regions, and
prior to forming the first and second segments, each sub-region of the plurality of sub-regions exposes a portion of a surface of a respective tier of the second plurality of tiers.

16. The method of claim 15, wherein:
removing the first segment, the second segment, and each tier of the second plurality of tiers comprises forming respective second cavities between each sub-region and exhuming the second dielectric material from the first segment, the second segment, and each tier of the second plurality of tiers via the respective second cavities; and
forming the word line and the word line contact comprises depositing, via the respective second cavities, a conductive material within voids formed by the exhuming of the second dielectric material from the first segment the second segment, and each tier of the second plurality of tiers.

17. The method of claim 13, further comprising:
depositing, prior to forming the first segment and the second segment, a third dielectric material on sidewalls of the first cavity.

18. The method of claim 13, wherein the first segment extends from the first tier of the second plurality of tiers along the direction orthogonal to the substrate and towards a top surface of the stack of tiers.

19. The method of claim 13, wherein the second segment extends from the first tier of the second plurality of tiers along the direction orthogonal to the substrate and towards the substrate.

20. The method of claim 13, further comprising:
forming a second word line in place of a second removed tier of the second plurality of tiers; and
forming a second word line contact in place of a third segment comprising the second dielectric material, wherein the second word line contact is offset from the word line contact along a direction parallel to a surface of the substrate.
